(19) United States
(12) Patent Application Publication
(10) Pub. No.: US 2026/0186426 A1
(43) Pub. Date: Jul. 2, 2026

(54) DETERMINING A FOCUS POSITION BASED ON A FIELD IMAGE POSITION SHIFT

(71) Applicant: ASML Netherlands B.V., Veldhoven (NL)

(72) Inventors: Chien Jung HUANG, Taipei (TW); Roxana REZVANI NARAGHI, Easton, CT (US); Raul Andres GUEVARA TORRES, Norwalk, CT (US); Marissa GRANADOS-BAEZ, Norwalk, CT (US)

(73) Assignee: ASML Netherlands B.V., Veldhoven (NL)

(21) Appl. No.: 19/131,135

(22) PCT Filed: Nov. 8, 2023
(86) PCT No.: PCT/EP2023/081205

§ 371 Date: May 19, 2025

Related U.S. Application Data
(60) Provisional application No. 63/429,666, filed on Dec. 2, 2022.

(51) Int. Cl. G03F 7/00; H10W 46/00

(52) U.S. Cl. CPC G03F 7/70725; G03F 7/70525; G03F 7/70633; G03F 7/70641; G03F 7/706849; G03F 7/706851; G03F 7/70775; H10W 46/301

(57) ABSTRACT

The metrology system(s) and method(s) described herein eliminate the need for a separate focus branch (e.g., comprising an illumination source, several lenses, and many other optical components) often used in prior metrology systems to determine a focus position for imaging a substrate. Instead of using a separate focus branch, the present system(s) and method(s) use the position of a field image taken of the substrate in the ordinary course of a metrology measurement using existing sensing components to determine the focus position. A shift of the field image position from an expected field image position is determined, and the focus position for imaging the substrate is determined based on the shift.

### CROSS-REFERENCE TO RELATED APPLICATION

This application claims priority of U.S. application 63/429,666 which was filed on 2 Dec. 2022, and which is incorporated herein in its entirety by reference.

### TECHNICAL FIELD

This description relates to determining a focus position based on a field image position shift.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate includes a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively.

Prior to transferring the pattern from the patterning device to the substrate, the substrate may undergo various procedures, such as priming, resist coating, and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, deposition, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc. This device manufacturing process may be considered a patterning process.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but are not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

### SUMMARY

The metrology system(s) and method(s) described below eliminate the need for a separate focus branch (e.g., comprising an illumination source, several lenses, and many other optical components) often used in prior metrology systems to determine a focus position for imaging a substrate. Instead of using a separate focus branch, the present system(s) and method(s) use the position of a field image taken of the substrate in the course of a metrology measurement using existing sensing components to determine the focus position. A shift of the field image position from an expected field image position is determined, and the focus position for imaging the substrate is determined based on the shift.

According to an embodiment, a metrology system is provided. The system comprises a radiation sensor configured to receive radiation and generate a signal indicative of a field image position of the radiation. The system comprises an optical component configured to receive the radiation reflected from a substrate, change an angle of the radiation, and direct the radiation toward the sensor. The system comprises one or more processors operatively connected with the radiation sensor and configured to: determine a shift of the field image position from an expected field image position based on the changed angle; and determine a focus position for imaging the substrate based on the shift.

In some embodiments, the focus position is determined based on a linear relationship between the shift and a metrology system objective defocus.

In some embodiments, the optical component comprises a wedge. In some embodiments, defocused radiation incident on a wedge pupil plane causes the shift. In some embodiments, the wedge comprises quadrants, with each quadrant configured to direct a portion of the radiation to a different region of interest of the sensor to form spots of radiation on the sensor.

In some embodiments, the spots of radiation comprise two spots of radiation associated with 0th order diffracted radiation from the substrate, and two spots of radiation associated with 1st order diffracted radiation from the substrate. In some embodiments, the signal generated by the sensor is indicative of four separate field image positions of the spots of radiation. The one or more processors are configured to determine shifts of 0th order and 1st order spots, and determine the focus position based on the shifts of the 0th order and the 1st order spots.

In some embodiments, the one or more processors are configured to automatically adjust a location of a stage of the metrology system holding the substrate based on the focus position so that a subsequent image of the substrate is in focus.

In some embodiments, the one or more processors are configured to determine the shift of the field image position of a field image based on a centroid of spots of radiation in the field image. In some embodiments, the one or more processors are configured to determine the shift of the field image position of a field image based on an intensity of the field image. In some embodiments, the intensity is determined at one or more halves of one or more annuluses of spots of radiation in the field image.

In some embodiments, the substrate comprises a semiconductor wafer having one or more overlay targets configured to reflect the radiation toward the optical component.

In some embodiments, the sensor comprises a camera, a charge coupled device (CCD) array, a complementary metal oxide semiconductor (CMOS), and/or a photodiode array.

In some embodiments, the sensor comprises a micro diffraction based overlay camera associated with overlay measurement. In some embodiments, the sensor comprises a second camera separate from a micro diffraction based overlay camera in the metrology system associated with overlay measurement.

In some embodiments, the optical component comprises a micro diffraction based overlay wedge with high reflectivity beam splitters configured to direct the radiation from the substrate to the micro diffraction based overlay camera and the second camera at the same time.

In some embodiments, the system comprises a radiation source and one or more lenses. The radiation source and the one or more lenses are configured to generate the radiation and direct the radiation toward the substrate.

In some embodiments, the optical component, the sensor, and the one or more processors are configured for overlay detection. In some embodiments, the radiation received by the optical component is a micro diffraction based overlay signal, and the overlay detection is micro diffraction based overlay detection. In some embodiments, the metrology system is configured for a semiconductor wafer, and is used in a semiconductor manufacturing process.

According to another embodiment, a metrology method is provided. The method comprises receiving radiation reflected from a substrate with an optical component, changing an angle of the radiation, and directing the radiation toward a sensor. The method comprises receiving the radiation from the optical component with a radiation sensor, and generating a signal indicative of a field image position of the radiation. The method comprises determining, with one or more processors operatively connected with the radiation sensor, a shift of the field image position from an expected field image position based on the changed angle; and determining, with the one or more processors, a focus position for imaging the substrate based on the shift.

### BRIEF DESCRIPTION OF THE DRAWINGS

The above aspects and other aspects and features will become apparent to those ordinarily skilled in the art upon review of the following description of specific embodiments in conjunction with the accompanying figures.

FIG. 1 schematically depicts a lithography apparatus, according to an embodiment.

FIG. 2 schematically depicts an embodiment of a lithographic cell or cluster, according to an embodiment.

FIG. 3 schematically depicts an example inspection system, according to an embodiment.

FIG. 4 schematically depicts an example metrology technique, according to an embodiment.

FIG. 5 illustrates the relationship between a radiation illumination spot of an inspection system and a metrology target, according to an embodiment.

FIG. 6 illustrates a system configured for determining a focus position for imaging one or more metrology targets, according to an embodiment.

FIG. 7 illustrates receiving radiation reflected from a substrate with an optical component, changing an angle of the radiation, and directing the radiation toward a sensor; receiving the radiation from the optical component with a radiation sensor, and generating a signal indicative of a field image position of the radiation; and determining a shift of the field image position from an expected field image position based on the changed angle, according to an embodiment.

FIG. 8 illustrates how, depending on the target that reflects radiation, four different shifts for eight different spots may be available to use to determine a shift of a field image position relative to an expected position, according to an embodiment.

FIG. 9 illustrates determining a shift of the field image position of a field image based on an intensity (and/or an image indicative of the intensity) of the field image and/or one or more half annulus portions of the field image, according to an embodiment.

FIG. 10 illustrates improving the speed (compared to prior systems) of the focus position determination by sending 0th order radiation to a fast camera or sensor array, according to an embodiment.

FIG. 11 illustrates a metrology method, according to an embodiment.

FIG. 12 is a block diagram of an example computer system, according to an embodiment.

### DETAILED DESCRIPTION

In semiconductor device manufacturing, metrology operations typically include determining the position of a metrology mark (or marks) and/or other target in a layer of a semiconductor device structure. This position is typically determined by irradiating a metrology mark with radiation, and comparing characteristics of different diffraction orders of radiation reflected from the metrology mark. Such techniques are used to measure overlay, alignment, and/or other parameters.

Many metrology systems include a separate focus branch (e.g., a portion of a metrology system comprising a radiation source, several lenses, and many other optical components) to determine a focus position for imaging a substrate. A typical focus branch is bulky and expensive. It requires an extra beam splitter to combine the focus branch with the rest of the metrology system, which decreases radiation throughput to a central sensor. Because it has its own radiation source, a chromatic defocus calibration is needed due to a change in wavelength between the central sensor and the focus branch. Further, the focus position determination in such a system is not continuous because radiation used to determine the focus position travels along at least a portion of the same optical path as radiation eventually used for metrology measurements. This means that the metrology system switches back and forth between a focus position determination mode where the radiation source and optics in the focus branch are “on”, and a metrology image acquisition mode where the radiation source and optics in the focus branch are “off”. A focus gap between these modes can cause overlay error due to defocus and/or other problems. In addition, diffracted light of different orders from a metrology target on a substrate has different focus positions based on an objective wavefront error, which current metrology systems do not account for.

Advantageously, instead of using a separate focus branch, the present system(s) and method(s) use the position of a field image taken of the substrate in the course of a metrology measurement using existing sensing components to determine the focus position. A shift of the field image position from an expected field image position is determined, and the focus position for imaging the substrate is determined based on the shift. For example, an existing optical component in the sensing branch of a metrology system changes the angle of radiation received from a target on a substrate and directs the radiation to different regions of interest on a sensor (e.g., a camera). A defocus ray has a different incident angle on a pupil plane of the optical component, which causes a shift of the radiation incident on the different regions of the sensor. The displacement is present both in the 0th and 1st order radiation spots on the sensor. The focus position is determined based on a linear relationship between the shift and a metrology system objective defocus.

By way of a brief introduction, the description below relates to semiconductor device manufacturing and patterning processes. The following paragraphs also describe several components of systems and/or methods for semiconductor device metrology. These systems and methods may be used for measuring overlay, alignment, etc., in a semiconductor device manufacturing process, for example, or for other operations.

Although specific reference may be made in this text to the measurement of overlay, alignment, or other parameters, and the manufacture of integrated circuits (ICs) for semiconductor devices, it should be understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle,” “wafer” or “die” in this text should be considered as interchangeable with the more general terms “mask,” “substrate” and “target portion,” respectively.

The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

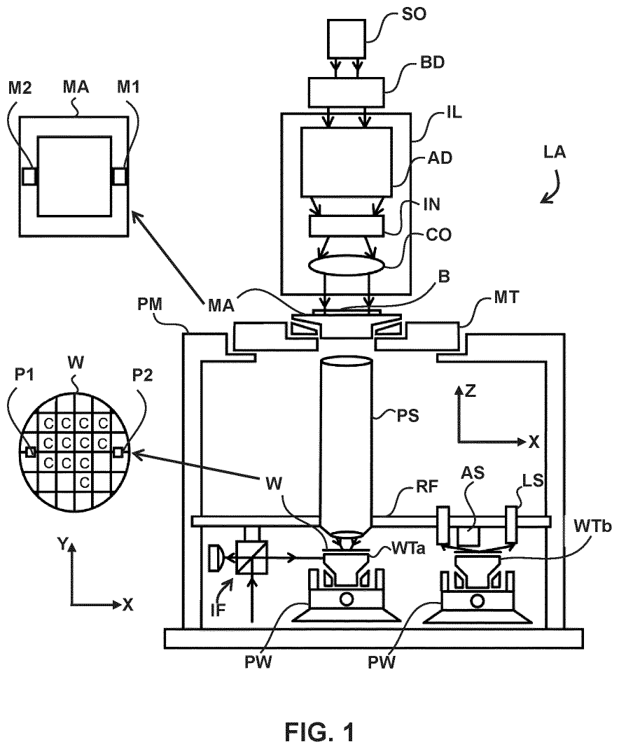

FIG. 1 schematically depicts an embodiment of a lithographic apparatus LA. The apparatus comprises an illumination system (illuminator) IL configured to condition a radiation beam B (e.g. UV radiation, DUV radiation, or EUV radiation); a support structure (e.g. a mask table) MT constructed to support a patterning device (e.g. a mask) MA and connected to a first positioner PM configured to accurately position the patterning device in accordance with certain parameters; a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame RF. As depicted, the apparatus is of a transmissive type (e.g. employing a transmissive mask). Alternatively, the apparatus may be of a reflective type (e.g. employing a programmable mirror array, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as σ-outer and σ-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic or other types of optical components, or any combination thereof, for directing, shaping, or controlling radiation. Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in a target portion of the device, such as an integrated circuit.

A patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The term “projection system” should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system.”

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z, or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g. astigmatic) and/or a high frequency shape (e.g. free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be conducted on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate. An immersion liquid may also be applied to other spaces in the lithographic apparatus, for example, between the patterning device and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder, 2-D encoder or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes. In step mode, the support structure MT and the substrate table WT are kept essentially stationary, while a pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above-described modes of use or entirely different modes of use may also be employed.

The substrate may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already includes multiple processed layers.

The terms “radiation” and “beam” used herein with respect to lithography encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, CD, edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns.

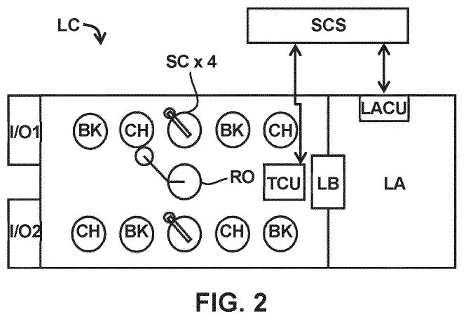

As shown in FIG. 2, the lithographic apparatus LA may form part of a lithographic cell LC, also sometimes referred to a lithocell or cluster, which also includes apparatuses to perform pre- and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)). The one or more measured parameters may include, for example, alignment, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement is often performed on one or more dedicated metrology targets provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. A fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. Traditionally, this may be termed diffraction-based metrology. Applications of this diffraction-based metrology include the measurement of overlay, alignment, etc. For example, overlay and/or alignment can be measured by comparing parts of the diffraction spectrum (for example, comparing different diffraction orders in the diffraction spectrum of a periodic grating).

Thus, in a device fabrication process (e.g., a patterning process or a lithography process), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)).

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications. Other manufacturing process adjustments are contemplated.

A metrology system may be used to determine one or more properties of the substrate structure, and in particular, how one or more properties of different substrate structures vary, or different layers of the same substrate structure vary from layer to layer. The metrology system may be integrated into the lithographic apparatus LA or the lithocell LC, or may be a stand-alone device.

To enable the metrology, often one or more targets are specifically provided on the substrate. Typically, the target is specially designed and may comprise a periodic structure. For example, the target on a substrate may comprise one or more 1-D periodic structures (e.g., geometric features such as gratings), which are printed such that after development, the periodic structural features are formed of solid resist lines. As another example, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

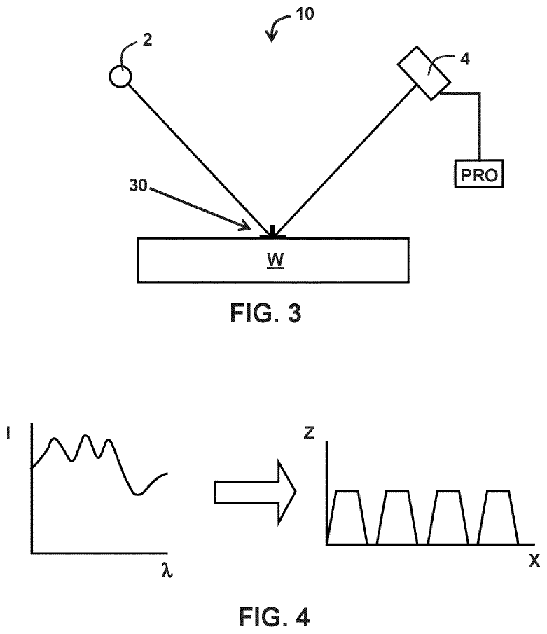

FIG. 3 depicts an example metrology (inspection) system 10 that may be used to detect overlay, alignment, and/or perform other metrology operations. It comprises a radiation or illumination source 2 which projects or otherwise irradiates radiation onto a substrate W (e.g., which may typically include a metrology mark). The redirected radiation is passed to a sensor such as a spectrometer detector 4 and/or other sensors, which measures a spectrum (intensity as a function of wavelength) of the specular reflected and/or diffracted radiation, as shown, e.g., in the graph on the left of FIG. 4. The sensor may generate a metrology signal conveying metrology data indicative of properties of the reflected radiation. From this data, the structure or profile giving rise to the detected spectrum may be reconstructed by one or more processors PRO, a generalized example of which is shown in FIG. 4, or by other operations.

As in the lithographic apparatus LA in FIG. 1, one or more substrate tables (not shown in FIG. 4) may be provided to hold the substrate W during measurement operations. The one or more substrate tables may be similar or identical in form to the substrate table WT (WTa or WTb or both) of FIG. 1. In an example where inspection system 10 is integrated with the lithographic apparatus, they may even be the same substrate table. Coarse and fine positioners may be provided and configured to accurately position the substrate in relation to a measurement optical system. Various sensors and actuators are provided, for example, to acquire the position of a target portion of interest of a structure (e.g., a metrology mark), and to bring it into position under an objective lens. Typically, many measurements will be made on target portions of a structure at different locations across the substrate W. The substrate support can be moved in X and Y directions to acquire different targets, and in the Z direction to obtain a desired location of the target portion relative to the focus of the optical system. It is convenient to think and describe operations as if the objective lens is being brought to different locations relative to the substrate, when, for example, in practice the optical system may remain substantially stationary (typically in the X and Y directions, but perhaps also in the Z direction) and the substrate moves. Provided the relative position of the substrate and the optical system is correct, it does not matter in principle which one of those is moving, or if both are moving, or a combination of a part of the optical system is moving (e.g., in the Z and/or tilt direction) with the remainder of the optical system being stationary and the substrate is moving (e.g., in the X and Y directions, but also optionally in the Z and/or tilt direction).

For typical metrology measurements, a target 30 on substrate W may be a 1-D grating, which is printed such that after development, the bars are formed of solid resist lines (e.g., which may be covered by a deposition layer), and/or other materials. Or the target 30 may be a 2-D grating, which is printed such that after development, the grating is formed of solid resist pillars, and/or other features in the resist.

The bars, pillars, vias, and/or other features may be etched into or on the substrate (e.g., into one or more layers on the substrate), deposited on a substrate, covered by a deposition layer, and/or have other properties. Target (portion) 30 (e.g., of bars, pillars, vias, etc.) is sensitive to changes in processing in the patterning process (e.g., optical aberration in the lithographic projection apparatus such as in the projection system, focus change, dose change, etc.) such that process variation manifests in variation in target 30. Accordingly, the measured data from target 30 may be used to determine an adjustment for one or more of the manufacturing processes, and/or used as a basis for making the actual adjustment.

For example, the measured data from target 30 may indicate overlay for a layer of a semiconductor device. The measured data from target 30 may be used (e.g., by the one or more processors PRO and/or other processors) for determining one or more semiconductor device manufacturing process parameters based the overlay, and determining an adjustment for a semiconductor device manufacturing apparatus based on the one or more determined semiconductor device manufacturing process parameters. In some embodiments, this may comprise a stage position adjustment, for example, or this may include determining an adjustment for a mask design, a metrology target design, a semiconductor device design, an intensity of the radiation, an incident angle of the radiation, a wavelength of the radiation, a pupil size and/or shape, a resist material, and/or other process parameters.

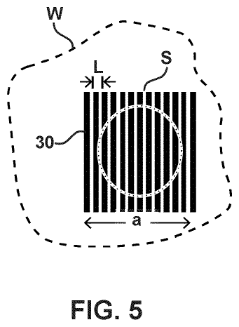

FIG. 5 illustrates a plan view of a typical target (e.g., metrology mark) 30, and the extent of a typical radiation illumination spot S in the system of FIG. 4. Typically, to obtain a diffraction spectrum that is free of interference from surrounding structures, the target 30, in an embodiment, is a periodic structure (e.g., grating) larger than the width (e.g., diameter) of the illumination spot S. The width of spot S may be smaller than the width and length of the target. The target, in other words, is ‘underfilled’ by the illumination, and the diffraction signal is essentially free from any signals from product features and the like outside the target itself. The illumination arrangement may be configured to provide illumination of a uniform intensity across a back focal plane of an objective, for example. Alternatively, by, for example, including an aperture in the illumination path, illumination may be restricted to on axis or off axis directions.

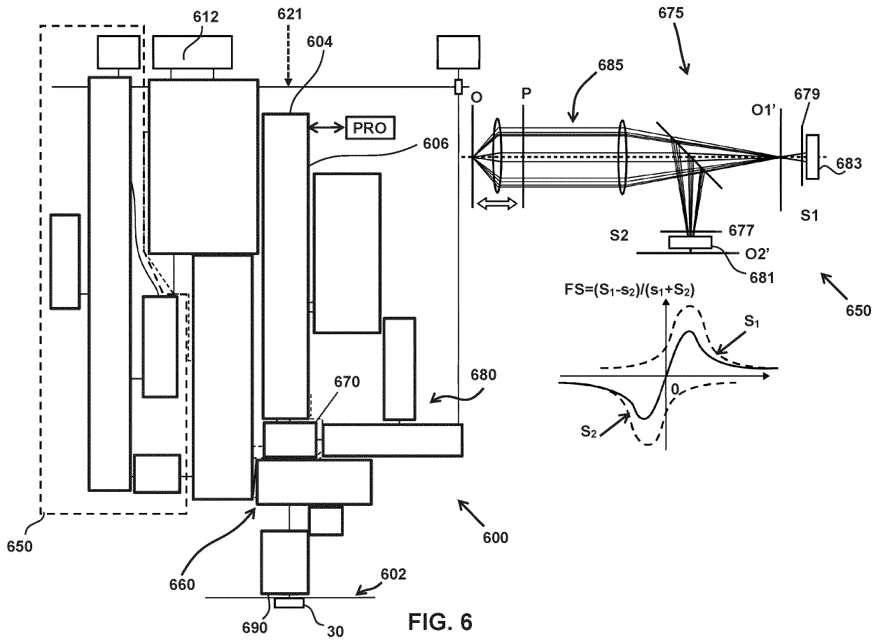

FIG. 6 illustrates a system 600 configured for determining a focus position for imaging one or more metrology targets 30. A target 30 may comprise one or more metrology marks, such as diffraction grating targets, formed in a substrate 602 such as a semiconductor wafer, collectively referred to as target 30, for example. Target 30 may comprise one or more structures in the patterned substrate capable of providing a diffraction signal. One or more targets 30 may be included in a layer of a substrate in a semiconductor device structure, for example. In some embodiments, the feature comprises a geometric feature such as a 1D or 2D feature, and/or other geometric features. By way of several non-limiting examples, the feature may comprise a grating, a line, an edge, a fine-pitched series of lines and/or edges, and/or other features.

System 600 comprises a radiation sensor 604 configured to receive radiation from target 30 and generate a signal indicative of a field image position of the radiation. The radiation may be used to obtain images of the metrology targets 30, and/or for other uses. The radiation may comprise illumination such as light and/or other radiation. System 600 comprises an optical component 606 configured to receive the radiation reflected from target 30 and substrate 602, change an angle of the radiation, and direct the radiation toward sensor 604. System 600 comprises one or more processors PRO operatively connected with radiation sensor 604 and configured to: determine a shift of the field image position from an expected field image position based on the changed angle; and determine a focus position for imaging the substrate based on the shift and/or other information.

System 600 may be similar to and/or the same as system 10 shown in FIG. 3. In FIG. 6, additional detail is illustrated for system 600 compared to system 10. In some embodiments, system 600 may form a portion of system 10 described above with respect to FIG. 3. System 600 may be a subsystem of system 10, for example. In some embodiments, one or more components of system 600 may be similar to and/or the same as one or more components of system 10. In some embodiments, one or more components of system 600 may replace, be used with, and/or otherwise augment one or more components of system 10.

System 600 comprises radiation source 612; optical component 606; an overlay detection branch 660 with a sensor 604; a beam splitter 670; an alignment branch 680; various lenses, reflectors, and other optical components (with an example objective lens 690 labeled in FIG. 6); and/or other components. In some embodiments, the components of system 600 form a portion of an overlay and/or alignment sensor that is used in a semiconductor manufacturing process. Radiation source 612 is configured to generate radiation along a first optical path 621. The radiation may have a target wavelength and/or wavelength range, a target intensity, and/or other characteristics. The target wavelength and/or wavelength range, the target intensity, etc., may be entered and/or selected by a user, determined by the system (e.g., system 10 shown in FIG. 3) based on previous measurements, and/or determined in other ways. In some embodiments, the radiation comprises light and/or other radiation. In some embodiments, the light comprises visible light, infrared light, near infrared light, and/or other light. In some embodiments, the radiation may be any radiation appropriate for interferometry.

As described above, system 600 does not include a separate focus branch 650 (illustrated as removed in FIG. 6). A focus measurement 675 made by focus branch 650 requires detection apertures 677 and 679 along with corresponding sensors 681 and 683 before focus and another after focus. A zero-defocus position is defined when the two sensors detect the same radiation 685 intensity. Intensity is determined before and after a focus position conjugate to a substrate, and a normalized difference is determined to be the focus position. In FIG. 6, FS stands for Focus Signal (e.g., a representation of a (best) focus position) which has been determined for prior systems by the equation for FS shown in FIGS. 6, S1 and S2 are first and second intensities at the respective sensors, O stands for object which in this example can be a substrate (e.g., a wafer) plane, O1′/O2′ represent a conjugate plane of O, and P is a pupil plane.

System 600 provides a new optical design architecture. Instead of using focus branch 650 and the principles of focus measurement described above, system 600 uses the position of a field image taken of target 30 in the substrate in the course of a metrology measurement using existing sensing components (e.g., sensor 604, optical component 606, etc.) to determine the focus position. This new architecture reduces costs and bulk compared to prior systems because the components of focus branch 650 are not required. This new architecture increases radiation throughput to sensor 604 because an extra beam splitter is no longer required to combine focus branch 650 with the rest of system 600. This new architecture does not require a chromatic focus calibration because there is no longer a change in radiation wavelength between sensor 604 and focus branch 650 (e.g., because focus branch 650 is no longer present at all). This new architecture provides a continuous focus determination because switching back and forth between a focus mode and a measurement mode is no longer required, accounts for objective wavefront error, and/or has other advantages.

Radiation reflected from target 30 in a substrate 602 such as wafer is received with optical component 606, which changes an angle of the radiation, and directs the radiation toward radiation sensor 604. In some embodiments, optical component 606 comprises a wedge and/or other optical components. In some embodiments, optical component 606 comprises a micro diffraction based overlay wedge. The wedge may comprise quadrants, for example. Each quadrant is configured to direct a portion of the radiation to a different region of interest of sensor 604 to form spots of radiation on sensor 604. The spots of radiation may comprise two spots of radiation associated with 0th order diffracted radiation from target 30 on a substrate, and two spots of radiation associated with 1st order diffracted radiation from target 30, for example.

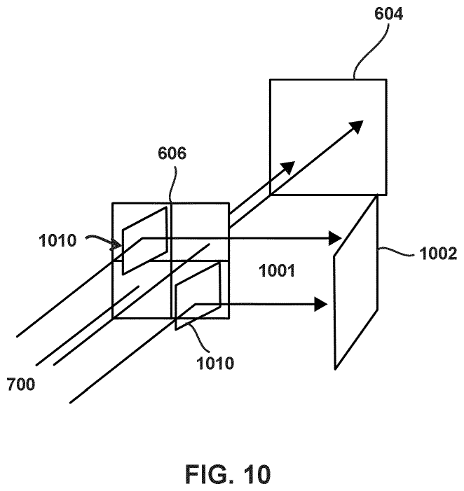

The radiation from optical component 606 is received with sensor 604, and a signal indicative of a field image position of the radiation is generated. Radiation sensor 604 may be similar to and/or the same as detector 4 and/or processors PRO shown in FIG. 3, and/or other components. In some embodiments, sensor 604 comprises a camera, a charge coupled device (CCD) array, a complementary metal oxide semiconductor (CMOS), a photodiode array, and/or other sensors. In some embodiments, sensor 604 comprises a micro diffraction based overlay camera associated with overlay measurement. In some embodiments, sensor 604 comprises a second camera separate from a micro diffraction based overlay camera in metrology system 600 associated with overlay measurement. In some embodiments, optical component 606 comprises a micro diffraction based overlay wedge with high reflectivity beam splitters configured to direct the radiation from the substrate to the micro diffraction based overlay camera and the second camera at the same time (e.g., as further described below related to FIG. 10).

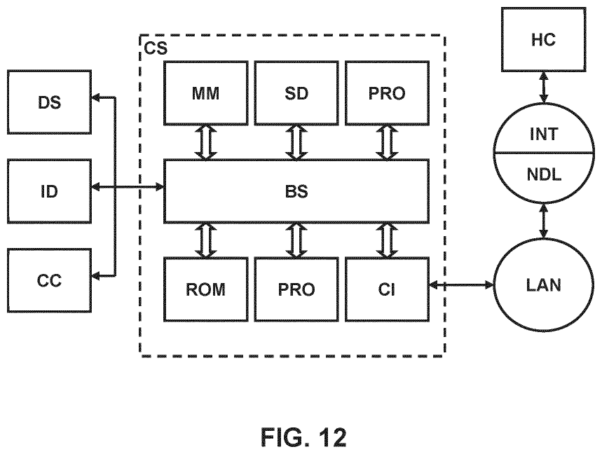

A shift of the field image position from an expected field image position is determined by one or more processors PRO based on the changed angle and/or other information. Defocused radiation incident on a wedge pupil plane causes the shift. The signal generated by sensor 604 is indicative of four separate field image positions of the spots of radiation. One or more processors PRO (e.g., and/or PRO shown in FIG. 3, and/or the processor(s) described below related to FIG. 12) may determine the shift of the field image position of a field image based on a centroid of spots of radiation in the field image. In some embodiments, the shift of the field image position of a field image is determined based on an intensity of the field image. In some embodiments, the intensity is determined at one or more halves of one or more annuluses of spots of radiation in the field image, for example.

A focus position for imaging target 30 on the substrate is determined based on the shift and/or other information. The focus position is determined based on a relationship between the shift and a metrology system objective defocus. This relationship may be linear and/or have other corresponding relationships. For example, one or more processors (e.g., PRO shown in FIG. 3 and/or the processor(s) described below related to FIG. 12) are configured to determine shifts of 0th order and 1st order spots, and determine the focus position based on the shifts of the 0th order and the 1st order spots. A linear relationship between the shift and objective defocus means that as defocus increases the spots that are farther from their expected positions. This shift and this relationship can be used to determine the (best) focus position for optical components such as objective 690 to image target 30.

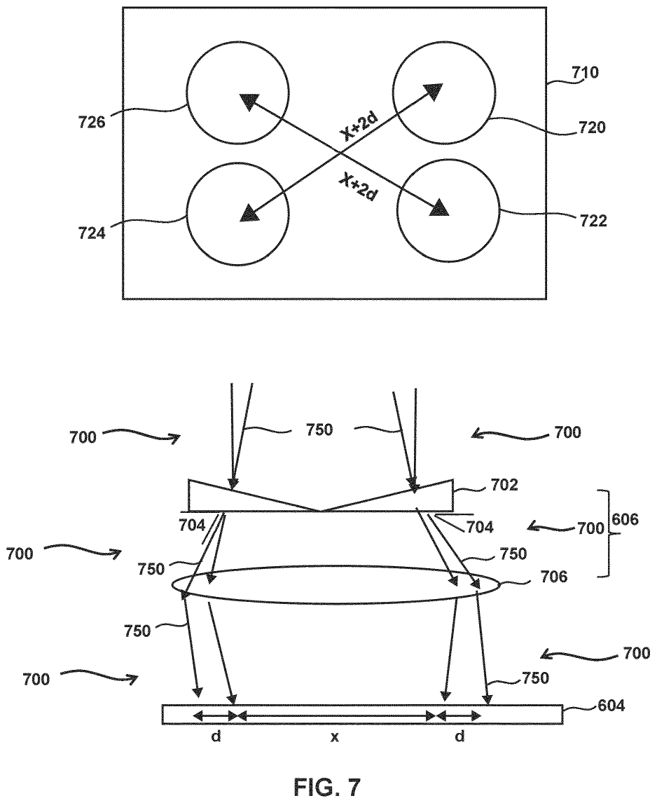

FIG. 7-10 illustrate various operations described above. For example, FIG. 7 illustrates receiving radiation 700 reflected from a target on a substrate with an optical component 606 comprising a wedge 702, changing an angle 704 of radiation 700, and directing radiation 700 toward sensor 604 (e.g., with a lens 706 of optical component 606). FIG. 7 also illustrates determining a shift “d” of a field image 710 position from an expected field image position “x” based on the changed angle 704 and/or other information. Defocused radiation 750 incident on a wedge pupil plane causes the shift “d”. Wedge 702 is configured to direct a portion of radiation 700 to a different region of interest of sensor 604 to form spots 720, 722, 724, and 726 of radiation 700 on sensor 604. The spots 720-726 of radiation 700 comprise two spots 720 and 724 of radiation associated with 0th order diffracted radiation from target 30 on a substrate, and two spots 722 and 726 of radiation associated with 1st order diffracted radiation from target 30, for example. As shown in FIG. 7, a defocus ray of radiation 750 will have a different incident angle on the wedge 702 pupil plane, and field image 710 with then have the shift “d”. The shift is present both in the 0th and 1st order spots 720-726.

The radiation 700 from optical component 606 is received with sensor 604, and a signal indicative of a field image position of spots 720-726 is generated. The signal generated by sensor 604 is indicative of four separate field image positions of the spots 720-726 of radiation 700. One or more processors PRO (e.g., and/or PRO shown in FIG. 3, FIG. 6, and/or the processor(s) described below related to FIG. 12) may determine the shift “d” of the field image position of a field image (e.g., a shift “d” for each spot) based on a centroid of spots 720-726 in field image 710, intensities of spots and/or portions of spots 720-726 of field image 710, and/or other information. For example, in some embodiments, one or more intensities may be determined at one or more halves of one or more annuluses of spots of radiation in the field image (e.g., because this may be a convenient area of a spot to analyze to determine whether a spot has moved from an expected position, as further described below). In some embodiments, a distance between spots 720 and 724 and/or 722 and 726 may be determined, for example, by binarizing image 710 with a grayscale threshold and/or using other methods. In the example shown in FIG. 7, spots 720-726 have moved from expected position “x” to locations at “x+2d”.

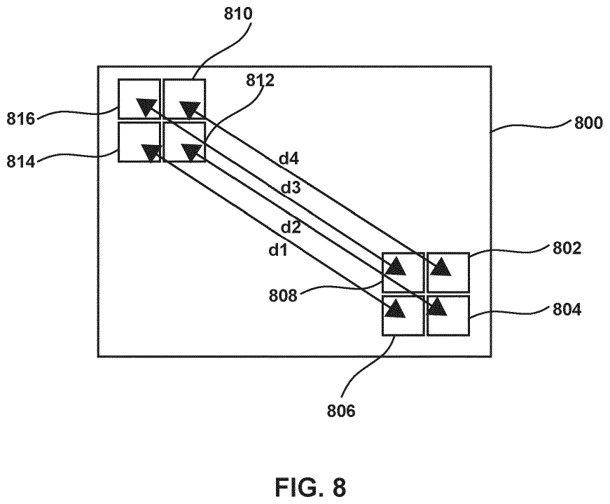

FIG. 8 illustrates how, depending on the target 30 that reflects radiation 700 (FIG. 7), four different shifts, d1, d2, d3, and d4 for eight different spots 802-816 in this example, may be available to use to determine a shift of a field image 800 position relative to an expected position. In some embodiments, d1-d4 are used (e.g., more or less may be used as needed) because each rectangle (for example) defining an area of a target uses a different area of the pupil plane. For example, 816 uses-1^{st} x and 808 uses+1^{st} x areas, 810 uses-1^{st} y and 802 uses+1^{st} y, in which their wavefronts are all different on the pupil plane. Because a typical metrology mark on a wafer has four small rectangles, each one comprising a grating, then at the uDBO camera (or other sensor) four copies exist, providing the possibility to measure multiple d's. The focus position can be determined to compensate for the aberration associated with a large NA (usually there is a high order aberration on high NA regions of interest). Based on this idea, the focus can be compensated for every point as a continuous focus.

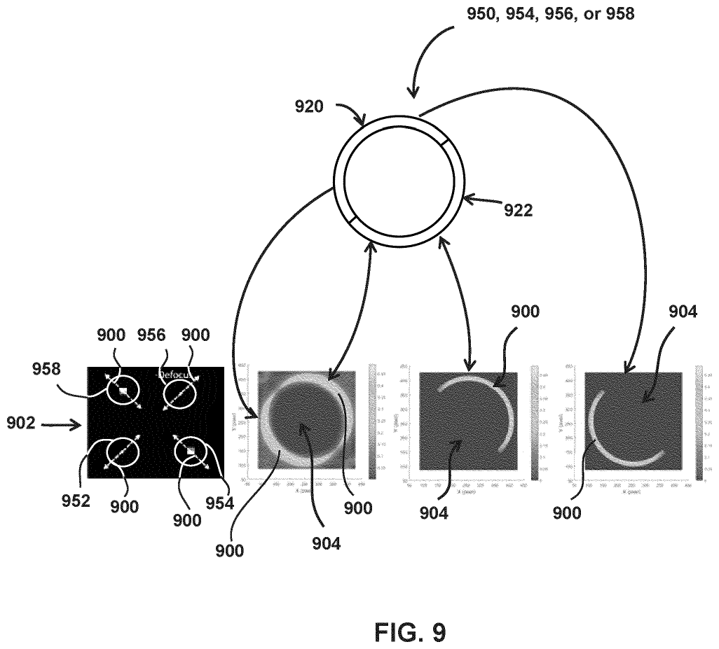

FIG. 9 illustrates determining a shift 900 of the field image position of a field image 902 based on an intensity 904 (and/or an image indicative of the intensity) of the field image and/or one or more portions 910 of field image 902. System 600 (FIG. 6) may be configured for contrast detection or intensity 904 variation detection of the centroid, the edge, and/or other areas of spots 952, 954, 956, and/or 958 in field image 902 as a function of the defocus. Two half annulus regions 920 and 922 at the edge of one or more spots 952-958 in image 902 can be defined as regions of interest. In some embodiments, intensity 904 is determined at the one or more half annulus regions 920 and 922 of spots 950, 952, 954, 956 of radiation in the field image, for example.

One or more intensities may be determined at half annulus regions 920 and/or 922 in field image 902 because this may be a convenient area of a spot 952-958 to analyze to determine whether a spot 952-958 has moved from an expected position. These regions of image 902 present the greatest change of intensity with defocus. In addition, each half annulus region 920 or 922 sees the opposite change in intensity with defocus. For example, an expected intensity 904 at or near the edge of a spot may be some non-zero value. If the intensity 904 at that spot turns out to be zero or close to zero, the spot may have shifted from its expected position. The opposite is also true (whether on an opposite side of the same spot, or on a different spot). An intensity in a certain location outside the expected position of a spot may be expected be zero, and if not, the spot may have shifted from its expected position. Processor PRO (FIG. 3, FIG. 6, FIG. 12) may determine the amount of this shift as described above, and use the (e.g., linear) relationship with defocus to determine a (best) focus position for imaging a target (e.g., target 30 shown in FIG. 6) in a substrate such as a semiconductor wafer. The intensity in half annulus portion 920 becomes S1 and the intensity in half annulus portion 922 becomes S2, with a focus signal FS determined as FS=(S1-S2)/(S1+S2), in this example.

FIG. 10 illustrates improving the speed (compared to prior systems) of the focus position determination by sending 0th order radiation 1001 to a fast camera or sensor array 1002. In some embodiments, the focus position determination can be made based on output signals from the fast camera or sensor array 1002, while overlay can be determined based on output signals from sensor 604. As described above, in some embodiments, sensor 604 comprises a micro diffraction based overlay camera associated with overlay measurement. In some embodiments, sensor 604 comprises a second camera, such as fast camera or sensor array 1002, separate from a micro diffraction based overlay camera (sensor 604) in metrology system 600 associated with overlay measurement. In some embodiments, optical component 606 comprises a micro diffraction based overlay wedge (optical component 606) with high reflectivity beam splitters 1010 configured to direct the radiation 700 from the substrate to the micro diffraction based overlay camera (sensor 604) and the second camera (e.g., 1002) at the same time.

Returning to FIG. 6, the various lenses (example objective lens 690 is labeled in FIG. 6), reflectors, and other optical components (e.g. such as optical component 606—e.g., a wedge) are configured to receive, transmit, reflect, focus, and/or perform other operations on the illumination generated by source 612, split by a beam splitter 670, transmitted or reflected by various optical elements, received by detection branch 660, received by alignment branch 680, and/or used by other portions of system 600. These various lenses, reflectors, and/or other optical components may comprise any type of lens, reflector, and/or other optical component configured to allow system 600 to function as described. For example, objective lens 690 may be formed from any transparent material and have curved surfaces configured to concentrate or otherwise focus one or more spots of radiation on target(s) 30. The various lenses, reflectors, optical elements, beam splitter, and other optical elements may be positioned in any location and/or at any angle relative to each other that allows system 600 to function as described herein. This may include positioning at specific relative distances between elements, specific angles between elements, etc. In some embodiments, the various lenses, reflectors, optical elements, beam splitters, and other optical components are positioned relative to each other in system 600 via structural members, clips, clamps, screws, nuts, bolts, adhesive, and/or other mechanical devices. In some embodiments, various ones of the lenses, reflectors, optical elements, beam splitters, and other optical elements are movable relative to each other. Movement may be configured to adjust locations of corresponding spots of illumination on one or more targets 30, for example. In some embodiments, movement comprises tilting, translating or otherwise changing a distance between various lenses, reflectors, and other optical components. Other examples of movement are contemplated.

In some embodiments, movement may be controlled electronically by a processor, such as processor PRO (and also in FIG. 3, and FIG. 12 discussed below). Processor PRO may be included in a computing system CS (FIG. 12) and may operate based on computer or machine readable instructions (e.g., as described below related to FIG. 12). Electronic communication may occur by transmitting electronic signals between separate components, transmitting data between separate components of system 600, transmitting values between separate components, and/or other communication. The components of system 600 may communicate via wires or wirelessly via a network, such as the Internet or the Internet in combination with various other networks, like local area networks, cellular networks, or personal area networks, internal organizational networks, and/or other networks.

In some embodiments, one or more actuators (not shown in FIG. 6) may be coupled to and configured to move one or more components of system 600. The actuators may be coupled to one or components of system 600 by adhesive, clips, clamps, screws, a collar, and/or other mechanisms. The actuators may be configured to be controlled electronically. Individual actuators may be configured to convert an electrical signal into mechanical displacement. The mechanical displacement is configured to move a component of system 600. As an example, one or more of the actuators may be piezoelectric. One or more processors PRO may be configured to control the actuators. One or more processors PRO may be configured to individually control each of the one or more actuators.

The quantity of the various lenses, reflectors, and/or other optical components shown in FIG. 6 is not intended to be limiting. The principles described herein may be extended such that, in some embodiments, system 600 comprises additional or fewer lenses, reflectors, and/or other optical components

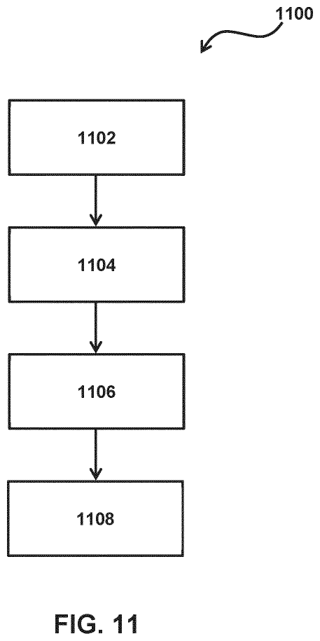

FIG. 11 illustrates a metrology method 1100 for determining a focus position for imaging a substrate. In some embodiments, method 1100 is performed as part of an overlay and/or alignment sensing operation in a semiconductor device manufacturing process, for example. In some embodiments, one or more operations of method 1100 may be implemented in or by system 600 illustrated in FIG. 6, system 10 illustrated in FIG. 3, a computer system (e.g., as illustrated in FIG. 12 and described below), and/or in or by other systems, for example. In some embodiments, method 1100 comprises receiving (operation 1102) radiation reflected from a substrate with an optical component, changing an angle of the radiation, and directing the radiation toward a radiation sensor; receiving (operation 1104) the radiation from the optical component with the radiation sensor and generating (operation 1104) a signal indicative of a field image position of the radiation; determining (operation 1106) a shift of the field image position from an expected field image position based on the changed angle; determining (operation 1108) a focus position for imaging the substrate based on the shift, and/or other operations.

The operations of method 1100 are intended to be illustrative. In some embodiments, method 1100 may be accomplished with one or more additional operations not described, and/or without one or more of the operations discussed. For example, in some embodiments, method 1100 may include an additional operation comprising determining an adjustment for a semiconductor device manufacturing process. Additionally, the order in which the operations of method 1100 are illustrated in FIG. 11 and described herein is not intended to be limiting.

In some embodiments, one or more portions of method 1100 may be implemented in and/or controlled by one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 1100 in response to instructions stored electronically on an electronic storage medium. The one or more processing devices may include one or more devices configured through hardware, firmware, and/or software to be specifically designed for execution of one or more of the operations of method 1100 (e.g., see discussion related to FIG. 12 below).

At operation 1102, radiation reflected from a substrate is received with an optical component, which changes an angle of the radiation, and directs the radiation toward a radiation sensor. The radiation sensor may be similar to and/or the same as detector 4 and/or processors PRO shown in FIG. 3, and/or other components. In some embodiments, the optical component is similar to and/or the same as the wedge described above. The wedge comprises quadrants. Each quadrant is configured to direct a portion of the radiation to a different region of interest of the sensor to form spots of radiation on the sensor. The spots of radiation comprise two spots of radiation associated with 0th order diffracted radiation from the substrate, and two spots of radiation associated with 1st order diffracted radiation from the substrate.

At operation 1104 the radiation from the optical component is received with the sensor, and a signal indicative of a field image position of the radiation is generated. In some embodiments, the sensor comprises a camera, a charge coupled device (CCD) array, a complementary metal oxide semiconductor (CMOS), a photodiode array, and/or other sensors. In some embodiments, the sensor comprises a micro diffraction based overlay camera associated with overlay measurement. In some embodiments, the sensor comprises a second camera separate from a micro diffraction based overlay camera in the metrology system associated with overlay measurement. In some embodiments, the optical component comprises a micro diffraction based overlay wedge with high reflectivity beam splitters configured to direct the radiation from the substrate to the micro diffraction based overlay camera and the second camera at the same time.

At operation 1106, a shift of the field image position from an expected field image position is determined based on the changed angle and/or other information. Defocused radiation incident on a wedge pupil plane causes the shift. The signal generated by the sensor is indicative of four separate field image positions of the spots of radiation. One or more processors (e.g., PRO shown in FIG. 3 and/or the processor(s) described below related to FIG. 12) may determine the shift of the field image position of a field image based on a centroid of spots of radiation in the field image. In some embodiments, the shift of the field image position of a field image is determined based on an intensity of the field image. In some embodiments, the intensity is determined at one or more halves of one or more annuluses of spots of radiation in the field image.

At operation 1108, a focus position for imaging the substrate is determined based on the shift and/or other information. The focus position is determined based on a linear relationship between the shift and a metrology system objective defocus, for example. For example, one or more processors (e.g., PRO shown in FIG. 3 and/or the processor(s) described below related to FIG. 12) are configured to determine shifts of 0th order and 1st order spots, and determine the focus position based on the shifts of the 0th order and the 1st order spots.

In some embodiments, method 1100 includes determining overlay and/or alignment. Overlay and/or alignment are determined based on reflected diffracted radiation from a diffraction grating target on the substrate, the focus position, the shift, and/or other information.

In some embodiments, method 1100 includes illuminating (and/or otherwise irradiating) one or more targets (e.g., target 30 shown in FIG. 3) in a patterned substrate with radiation. The radiation comprises light and/or other radiation. The radiation may be generated by a radiation source (e.g., source 2 shown in FIG. 3). In some embodiments, the radiation may be directed by the radiation source onto multiple targes, a single target, sub-portions (e.g., something less than the whole) of a target, and/or onto a substrate in other ways. In some embodiments, the radiation may be directed by the radiation source onto the target in a time varying manner. For example, the radiation may be rastered over a target (e.g., by moving the target under the radiation) such that different portions of the target are irradiated at different times. As another example, characteristics of the radiation (e.g., wavelength, intensity, etc.) may be varied. This may create time varying data envelopes, or windows, for analysis. The data envelopes may facilitate analysis of individual sub-portions of a target, comparison of one portion of a target to another and/or to other targets (e.g., in other layers), and/or other analysis.

In some embodiments, method 1100 comprises detecting reflected radiation (with the radiation sensor described above) from one or more diffraction grating targets. Detecting reflected radiation comprises detecting one or more phase and/or amplitude (intensity) shifts in reflected radiation from one or more geometric features of the target(s). The one or more phase and/or amplitude shifts correspond to one or more dimensions of a target. For example, the phase and/or amplitude of reflected radiation from one side of a target is different relative to the phase and/or amplitude of reflected radiation from another side of the target.

Detecting the one or more phase and/or amplitude (intensity) shifts in the reflected radiation from the target comprises measuring local phase shifts (e.g., local phase deltas) and/or amplitude variations that correspond to different portions of a target. For example, the reflected radiation from a specific area of a target may comprise a sinusoidal waveform having a certain phase and/or amplitude. The reflected radiation from a different area of the target (or a target in a different layer) may also comprise a sinusoidal waveform, but one with a different phase and/or amplitude. Detected reflected radiation also comprises measuring a phase and/or amplitude difference in reflected radiation of different diffraction orders. Detecting the one or more local phase and/or amplitude shifts may be performed using Hilbert transformations, for example, and/or other techniques. Interferometry techniques and/or other operations may be used to measure phase and/or amplitude differences in reflected radiation of different diffraction orders.

In some embodiments, method 1100 comprises generating a metrology signal based on the detected reflected radiation from diffraction grating target(s), as described above. The metrology signal is generated by a sensor (such as detector 4 in FIG. 3, a camera, and/or other sensors) based on radiation received by the sensor. The metrology signal comprises measurement information pertaining to the target(s) on a substrate. For example, the metrology signal may be an overlay and/or alignment signal comprising overlay and/or alignment measurement information, and/or other metrology signals. The measurement information (e.g., an overlay value, an alignment value, and/or other information) may be determined using principles of interferometry and/or other principles.

The metrology signal comprises an electronic signal that represents and/or otherwise corresponds to the radiation reflected from the target(s). The metrology signal may indicate a metrology value associated with a diffraction grating target, for example, and/or other information. Generating the metrology signal comprises sensing the reflected radiation and converting the sensed reflected radiation into the electronic signal. In some embodiments, generating the metrology signal comprises sensing different portions of the reflected radiation from different areas and/or different geometries of the target, and/or multiple targets, and combining the different portions of the reflected radiation to form the metrology signal. This may include generating and/or analyzing one or more images of a target, using the radiation described herein. This sensing and converting may be performed by components similar to and/or the same as detector 4 and/or processors PRO shown in FIG. 3, and/or other components.

In some embodiments, method 1100 comprises determining an adjustment for a semiconductor device manufacturing process. For example, this may include automatically adjusting, with the one or more processors, a location of a stage of a metrology system holding the substrate based on a determined focus position so that a subsequent image of the substrate is in focus. In some embodiments, method 1100 includes determining one or more semiconductor device manufacturing process parameters. The one or more semiconductor device manufacturing process parameters may be determined based on one or more detected phase and/or amplitude variations, an overlay and/or alignment value indicated by the metrology signal, and/or other similar systems, and/or other information. The one or more parameters may include a parameter of the radiation (the radiation used for metrology), an overlay value, an alignment value, a metrology inspection location on a layer of a semiconductor device structure, a radiation beam trajectory across a target, and/or other parameters. In some embodiments, process parameters can be interpreted broadly to include a stage position, a mask design, a metrology target design, a semiconductor device design, an intensity of the radiation (used for exposing resist, etc.), an incident angle of the radiation (used for exposing resist, etc.), a wavelength of the radiation (used for exposing resist, etc.), a pupil size and/or shape, a resist material, and/or other parameters.

In some embodiments, method 1100 includes determining a process adjustment based on the one or more determined semiconductor device manufacturing process parameters, adjusting a semiconductor device manufacturing apparatus based on the determined adjustment, and/or other operations. This may be performed by one or more processors such as PRO shown in FIG. 3, a processor described as part of the computer system illustrated in FIG. 12 and described below, and/or other processors. For example, if a determined metrology measurement is not within process tolerances, the out of tolerance measurement may be caused by one or more manufacturing processes whose process parameters have drifted and/or otherwise changed so that the process is no longer producing acceptable devices (e.g., measurements may breach a threshold for acceptability). One or more new or adjusted process parameters may be determined based on the measurement determination. The new or adjusted process parameters may be configured to cause a manufacturing process to again produce acceptable devices.

For example, a new or adjusted process parameter may cause a previously unacceptable measurement value to be adjusted back into an acceptable range. The new or adjusted process parameters may be compared to existing parameters for a given process. If there is a difference, that difference may be used to determine an adjustment for an apparatus that is used to produce the devices (e.g., parameter “x” should be increased/decreased/changed so that it matches the new or adjusted version of parameter “x” determined as part of method 1100), for example. In some embodiments, method 1100 may include electronically adjusting an apparatus (e.g., based on the determined process parameters). Electronically adjusting an apparatus may include sending an electronic signal, and/or other communications to the apparatus, for example, which causes a change in the apparatus. The electronic adjustment may include changing a setting on the apparatus, for example, and/or other adjustments.

FIG. 12 is a diagram of an example computer system CS that may be used for one or more of the operations described herein. Computer system CS includes a bus BS or other communication mechanism for communicating information, and a processor PRO (or multiple processors similar to and/or the same as processor PRO shown in FIG. 3) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a flat panel or touch panel display or a cathode ray tube (CRT) for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, all or some of one or more operations described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” or “machine-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM.

Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

Various embodiments of the present systems and methods are disclosed in the subsequent list of numbered clauses. In the following, further features, characteristics, and exemplary technical solutions of the present disclosure will be described in terms of clauses that may be optionally claimed in any combination:
1. A metrology system, comprising: a radiation sensor configured to receive radiation and generate a signal indicative of a field image position of the radiation; an optical component configured to receive the radiation reflected from a substrate, change an angle of the radiation, and direct the radiation toward the sensor; and one or more processors operatively connected with the radiation sensor and configured to: determine a shift of the field image position from an expected field image position based on the changed angle; and determine a focus position for imaging the substrate based on the shift.
2. The system of clause 1, wherein the focus position is determined based on a linear relationship between the shift and a metrology system objective defocus.
3. The system of any of the previous clauses, wherein the optical component comprises a wedge.
4. The system of any of the previous clauses, wherein defocused radiation incident on a wedge pupil plane causes the shift.
5. The system of any of the previous clauses, wherein the wedge comprises quadrants, each quadrant configured to direct a portion of the radiation to a different region of interest of the sensor to form spots of radiation on the sensor.
6. The system of any of the previous clauses, wherein the spots of radiation comprise two spots of radiation associated with 0th order diffracted radiation from the substrate, and two spots of radiation associated with 1st order diffracted radiation from the substrate.
7. The system of any of the previous clauses, wherein the signal generated by the sensor is indicative of four separate field image positions of the spots of radiation, and wherein the one or more processors are configured to determine shifts of 0th order and 1st order spots, and determine the focus position based on the shifts of the 0th order and the 1st order spots.
8. The system of any of the previous clauses, wherein the one or more processors are further configured to automatically adjust a location of a stage of the metrology system holding the substrate based on the focus position so that a subsequent image of the substrate is in focus.
9. The system of any of the previous clauses, wherein the one or more processors are configured to determine the shift of the field image position of a field image based on a centroid of spots of radiation in the field image.
10. The system of any of the previous clauses, wherein the one or more processors are configured to determine the shift of the field image position of a field image based on an intensity of the field image.
11. The system of any of the previous clauses, wherein the intensity is determined at one or more halves of one or more annuluses of spots of radiation in the field image.
12. The system of any of the previous clauses, wherein the substrate comprises a semiconductor wafer having one or more overlay targets configured to reflect the radiation toward the optical component.
13. The system of any of the previous clauses, wherein the sensor comprises a camera, a charge coupled device (CCD) array, a complementary metal oxide semiconductor (CMOS), and/or a photodiode array.
14. The system of any of the previous clauses, wherein the sensor comprises a micro diffraction based overlay camera associated with overlay measurement.
15. The system of any of the previous clauses, wherein the sensor comprises a second camera separate from a micro diffraction based overlay camera in the metrology system associated with overlay measurement.
16. The system of any of the previous clauses, wherein the optical component comprises a micro diffraction based overlay wedge with high reflectivity beam splitters configured to direct the radiation from the substrate to the micro diffraction based overlay camera and the second camera at the same time.
17. The system of any of the previous clauses, further comprising a radiation source and one or more lenses, the radiation source and the one or more lenses configured to generate the radiation and direct the radiation toward the substrate.
18. The system of any of the previous clauses, wherein the optical component, the sensor, and the one or more processors are configured for overlay detection.
19. The system of any of the previous clauses, wherein the radiation received by the optical component is a micro diffraction based overlay signal, and the overlay detection is micro diffraction based overlay detection.
20. The system of any of the previous clauses, wherein the metrology system is configured for a semiconductor wafer, and is used in a semiconductor manufacturing process.
21. A metrology method, comprising: receiving radiation reflected from a substrate with an optical component, changing an angle of the radiation, and directing the radiation toward a sensor; receiving the radiation from the optical component with a radiation sensor, and generating a signal indicative of a field image position of the radiation; determining, with one or more processors operatively connected with the radiation sensor a shift of the field image position from an expected field image position based on the changed angle; and determining, with the one or more processors, a focus position for imaging the substrate based on the shift.
22. The method of clause 21, wherein the focus position is determined based on a linear relationship between the shift and a metrology system objective defocus.
23. The method of any of the previous clauses, wherein the optical component comprises a wedge.
24. The method of any of the previous clauses, wherein defocused radiation incident on a wedge pupil plane causes the shift.
25. The method of any of the previous clauses, wherein the wedge comprises quadrants, each quadrant configured to direct a portion of the radiation to a different region of interest of the sensor to form spots of radiation on the sensor.
26. The method of any of the previous clauses, wherein the spots of radiation comprise two spots of radiation associated with 0th order diffracted radiation from the substrate, and two spots of radiation associated with 1st order diffracted radiation from the substrate.
27. The method of any of the previous clauses, wherein the signal generated by the sensor is indicative of four separate field image positions of the spots of radiation, and wherein the one or more processors are configured to determine shifts of 0th order and 1st order spots, and determine the focus position based on the shifts of the 0th order and the 1st order spots.
28. The method of any of the previous clauses, further comprising, automatically adjusting, with the one or more processors, a location of a stage of a metrology system holding the substrate based on the focus position so that a subsequent image of the substrate is in focus.
29. The method of any of the previous clauses, further comprising determining, with the one or more processors, the shift of the field image position of a field image based on a centroid of spots of radiation in the field image.
30. The method of any of the previous clauses, further comprising determining, with the one or more processors, the shift of the field image position of a field image based on an intensity of the field image.
31. The method of any of the previous clauses, wherein the intensity is determined at one or more halves of one or more annuluses of spots of radiation in the field image.
32. The method of any of the previous clauses, wherein the substrate comprises a semiconductor wafer having one or more overlay targets configured to reflect the radiation toward the optical component.
33. The method of any of any of the previous clauses, wherein the sensor comprises a camera, a charge coupled device (CCD) array, a complementary metal oxide semiconductor (CMOS), and/or a photodiode array.
34. The method of any of the previous clauses, wherein the sensor comprises a micro diffraction based overlay camera associated with overlay measurement.
35. The method of any of the previous clauses, wherein the sensor comprises a second camera separate from a micro diffraction based overlay camera in the metrology system associated with overlay measurement.
36. The method of any of the previous clauses, wherein the optical component comprises a micro diffraction based overlay wedge with high reflectivity beam splitters configured to direct the radiation from the substrate to the micro diffraction based overlay camera and the second camera at the same time.
37. The method of any of the previous clauses, further comprising generating the radiation with a radiation source and one or more lenses, the radiation source and the one or more lenses configured to generate the radiation and direct the radiation toward the substrate.
38. The method of any of the previous clauses, wherein the optical component, the sensor, and the one or more processors are configured for overlay detection.
39. The method of any of the previous clauses, wherein the radiation received by the optical component is a micro diffraction based overlay signal, and the overlay detection is micro diffraction based overlay detection.
40. The method of any of the previous clauses, wherein the method is configured for a semiconductor wafer, and is used in a semiconductor manufacturing process.

concepts disclosed herein may be associated with any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers. In addition, the combination and sub-combinations of disclosed elements may comprise separate embodiments.

The descriptions above are intended to be illustrative, not limiting. Thus, it will be apparent to one skilled in the art that modifications may be made as described without departing from the scope of the claims set out below.

1-15. (canceled)

16. A metrology system, comprising:
a radiation sensor configured to receive radiation and generate a signal indicative of a field image position of the radiation;
an optical component configured to receive the radiation reflected from a substrate, change an angle of the radiation, and direct the radiation toward the sensor; and
one or more processors operatively connected with the radiation sensor and configured to:
determine a shift of the field image position from an expected field image position based on the changed angle; and
determine a focus position for imaging the substrate based on the shift of the field image position.

17. The system of claim 16, wherein the focus position is determined based on a linear relationship between the shift of the field image position and a metrology system objective defocus.

18. The system of claim 16, wherein the optical component comprises a optical wedge.

19. The system of claim 18, wherein defocused radiation incident on a pupil plane of the optical wedge causes the shift.

20. The system of claim 18, wherein the optical wedge comprises quadrants, each quadrant configured to direct a portion of the radiation to a different region of interest of the sensor to form spots of radiation on the sensor.

21. The system of claim 20, wherein the spots of radiation comprise two spots of radiation associated with 0^{th} order diffracted radiation from the substrate, and two spots of radiation comprising a plus 1^{st} order diffracted radiation and a minus 1^{st} order diffracted radiation from the substrate.

22. The system of claim 21, wherein the signal generated by the sensor is indicative of four separate field image positions of the four spots of radiation, and
wherein the one or more processors are configured to determine shifts of the 0^{th} order and the 1^{st} order spots, and determine the focus position based on the shifts of the 0^{th} order and the 1^{st} order spots.

23. The system of claim 16, wherein the one or more processors are further configured to automatically adjust a location of a stage of the metrology system holding the substrate based on the focus position so that a subsequent image of the substrate is in focus.

24. The system of claim 16, wherein the one or more processors are configured to determine the shift of the field image position of a field image based on a centroid of spots of radiation in the field image.

25. The system of claim 16, wherein the one or more processors are configured to determine the shift of the field image position of a field image based on an intensity of the field image.

26. The system of claim 25, wherein the intensity is determined at one or more halves of one or more annuluses of spots of radiation in the field image.

27. The system of claim 16, wherein the substrate comprises a semiconductor wafer having one or more overlay targets configured to reflect the radiation toward the optical component.

28. The system of claim 16, wherein the sensor comprises a camera, a charge coupled device (CCD) array, a complementary metal oxide semiconductor (CMOS), and/or a photodiode array.

29. The system of claim 28, wherein the sensor comprises a micro diffraction based overlay camera associated with overlay measurement.

30. The system of claim 28, wherein the sensor comprises a second camera separate from a micro diffraction based overlay camera in the metrology system associated with overlay measurement.
